(19) United States
(12) Patent Application Publication
(10) Pub. No.: US 2019/0164785 A1
(43) Pub. Date: May 30, 2019

(54) Substrate Processing Method and Substrate Processing Apparatus

(71) Applicant: TOKYO ELECTRON LIMITED, Tokyo (JP)

(72) Inventor: Yosuke KAWABUCHI, Kumamoto (JP)

(21) Appl. No.: 16/194,818

(22) Filed: Nov. 19, 2018

(30) Foreign Application Priority Data
Nov. 24, 2017 (JP) 2017-225690

(51) Int. Cl. H01L 21/67; H01L 21/02; B08B 3/04

(52) U.S. Cl. CPC H01L 21/67034; B08B 3/04; H01L 21/67051; H01L 21/02057

(57) ABSTRACT

There is provided a method of processing a substrate, which includes: forming a liquid film of an organic solvent on a front surface of the substrate; and drying the substrate with the liquid film formed thereon by heating the substrate in a state where a gas density around the substrate is larger than a gas density of air.

### CROSS-REFERENCE TO RELATED APPLICATION

This application is based upon and claims the benefit of priority from Japanese Patent Application No. 2017-225690, filed on Nov. 24, 2017, the entire contents of which are incorporated herein by reference.

### TECHNICAL FIELD

The present disclosure relates to a substrate processing method and a substrate processing apparatus.

### BACKGROUND

There has been conventionally known a substrate processing method in which a substrate is dried by shaking off IPA (isopropylalcohol) on the surface of the substrate by rotating the substrate in a state where a liquid film of IPA is formed on the surface of the substrate.

However, when the substrate is dried by the above-described substrate processing method, there is a possibility of pattern collapse such that a pattern formed on the substrate collapses while the substrate is being dried.

### SUMMARY

Some embodiments of the present disclosure provide a substrate processing method and a substrate processing apparatus capable of suppressing pattern collapse at the time of drying a substrate.

According to one embodiment of the present disclosure, there is provided a method of processing a substrate, including: forming a liquid film of an organic solvent on a front surface of the substrate; and drying the substrate with the liquid film formed thereon by heating the substrate in a state where a gas density around the substrate is larger than a gas density of air.

According to another embodiment of the present disclosure, there is provided a substrate processing apparatus which includes: a forming part configured to form a liquid film of an organic solvent on a front surface of a substrate; and a drying part configured to dry the substrate with the liquid film formed thereon by heating the substrate in a state where a gas density around the substrate is larger than a gas density of air.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view of a substrate processing system as viewed from above, according to an embodiment.

FIG. 2 is a schematic cross-sectional view of the substrate processing system as viewed from a side, according to the embodiment.

FIG. 3 is a view showing a configuration example of a liquid processing unit.

FIG. 4 is a view showing a configuration example of a drying unit.

FIG. 5 is a partially-enlarged schematic view of a wafer pattern.

FIG. 6 is a view showing a relationship between a gas density and a surface tension.

FIG. 7 is a flow chart showing a procedure of substrate processing.

### DETAILED DESCRIPTION

Hereinafter, modes (hereinafter referred to as “embodiments”) for implementing a substrate processing method and a substrate processing apparatus according to the present disclosure will be described in detail with reference to the drawings. It should be noted that the substrate processing method and the substrate processing apparatus according to the present disclosure are not limited by these embodiments. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

[1.Configuration of Substrate Processing System]

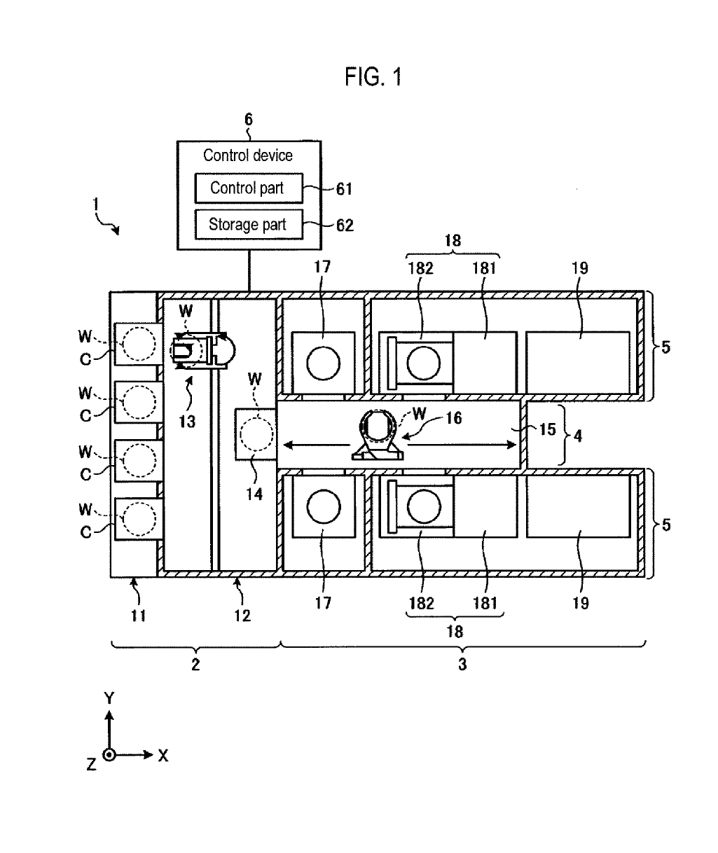

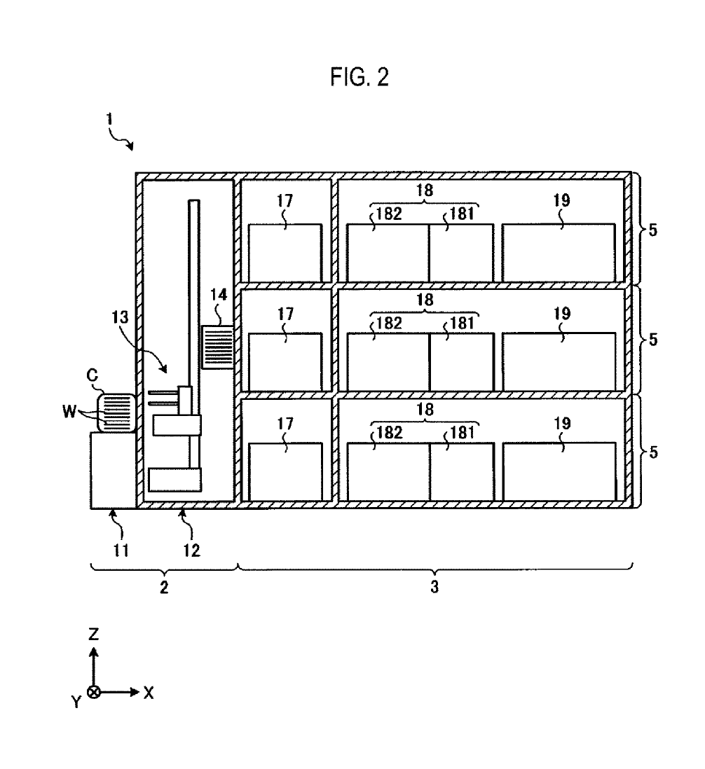

First, a configuration of a substrate processing system 1 according to an embodiment will be described with reference to FIGS. 1 and 2. FIG. 1 is a schematic cross-sectional view of the substrate processing system 1 as viewed from above, according to the embodiment. FIG. 2 is a schematic cross-sectional view of the substrate processing system 1 as viewed from a side, according to the embodiment. For the clarification of a positional relationship, an X-axis direction, a Y-axis direction and a Z-axis direction, which are orthogonal to one another, are defined in the following description and a positive Z-axis direction is defined as a vertical upward direction. The substrate processing system 1 constitutes a substrate processing apparatus.

As shown in FIG. 1, the substrate processing system 1 includes a loading/unloading station 2 and a processing station 3. The loading/unloading station 2 and the processing station 3 are installed adjacent to each other.

(Loading/Unloading Station)

The loading/unloading station 2 includes a carrier mounting part 11 and a transfer part 12. A plurality of carriers C configured to accommodate a plurality of semiconductor wafers W (hereinafter referred to as “wafers W”) in a horizontal posture is placed on the carrier mounting part 11.

The transfer part 12 is installed adjacent to the carrier mounting part 11. A transfer device 13 and a delivery part 14 are disposed inside the transfer part 12.

The transfer device 13 includes a wafer holding mechanism for holding the wafers W. Further, the transfer device 13 is capable of moving in horizontal and vertical directions, and swinging around a vertical axis. The transfer device 13 transfers the wafers W between the carriers C and the delivery part 14 using the wafer holding mechanism.

(Processing Station)

The processing station 3 is installed adjacent to the transfer part 12. The processing station 3 includes a transfer block 4 and a plurality of processing blocks 5.

(Transfer Block)

The transport block 4 includes a transport area 15 and a transfer device 16. The transfer area 15 is, for example, a rectangular parallelepiped area defined to extend along an arrangement direction (the X-axis direction) of the loading/unloading station 2 and the processing station 3. The transfer device 16 is disposed in the transfer area 15.

The transfer device 16 includes a wafer holding mechanism for holding the wafers W. In addition, the transfer device 16 is capable of moving in the horizontal and vertical directions, and swinging around a vertical axis. The transfer device 16 transfers the wafers W between the delivery part 14 and the plurality of processing blocks 5 using the wafer holding mechanism.

(Arrangement of Processing Blocks)

The plurality of processing blocks 5 is arranged adjacent to the transfer area 15 at both sides of the transfer area 15. Specifically, the plurality of processing blocks 5 is arranged at one side (in a positive Y-axis direction) and the other side (in a negative Y-axis direction) of the transfer area 15 in a direction (the Y-axis direction) perpendicular to the arrangement direction (the X-axis direction) of the loading/unloading station 2 and the processing station 3.

Further, as shown in FIG. 2, the plurality of processing blocks 5 is arranged in multiple stages along the vertical direction. In the present embodiment, the plurality of processing blocks 5 is arranged in three stages but is not limited thereto.

In this way, in the substrate processing system 1 according to the embodiment, the plurality of processing blocks 5 is arranged in multiple stages at both sides of the transfer block 4. The transfer of the wafers W between the processing blocks 5 arranged in the respective stages and the delivery part 14 is performed by a single transfer device 16 disposed in the transfer block 4. A plurality of transfer devices 16 may be installed in the transfer block 4.

(Internal Configuration of Processing Block)

Each of the processing blocks 5 includes a liquid processing unit 17, a drying unit 18 and a supply unit 19.

The liquid processing unit 17 performs a cleaning process of cleaning an upper surface (on which a pattern is to be formed) of the wafer W. Further, the liquid processing unit 17 performs a liquid film forming process of forming a liquid film on the upper surface (front surface) of the wafer W which has been subjected to the cleaning process. A configuration of the liquid processing unit 17 will be described later. The liquid processing unit 17 constitutes a forming part.

The drying unit 18 performs a drying process on the wafer W which has been subjected to the liquid film forming process. Specifically, the drying unit 18 dries the wafer W by heating the wafer W while keeping the surrounding of the wafer W after the liquid film forming process in an organic solvent gas atmosphere. A configuration of the drying unit 18 will be described later.

The organic solvent gas is a gas which has a higher density than that of air, and contains, for example, IPA, methanol, ethanol or the like. In the present embodiment, a gas containing gaseous IPA (hereinafter referred to as an “IPA gas”) is used as the organic solvent gas.

The supply unit 19 supplies a processing fluid to the drying unit 18. Specifically, the supply unit 19 includes a supply kit including a processing fluid tank, a flowmeter, a flow rate adjuster, a heater and the like, and a housing that accommodates the supply kit. In the present embodiment, the supply unit 19 supplies the IPA gas as the processing fluid to the drying unit 18. Further, the supply unit 19 supplies a N₂ gas, which is an inert gas, as the processing fluid to the drying unit 18.

The liquid processing unit 17, the drying unit 18 and the supply unit 19 are arranged along the transfer area 15 (namely along the X-axis direction). Of the liquid processing unit 17, the drying unit 18 and the supply unit 19, the liquid processing unit 17 is disposed at a position closest to the loading/unloading station 2, and the supply unit 19 is disposed at a position farthest from the loading/unloading station 2.

In this way, each of the processing blocks 5 has a single liquid processing unit 17, a single drying unit 18 and a single supply unit 19. That is to say, in the substrate processing system 1, the number of the liquid processing unit 17, the transfer device 16 and the supply unit 19 are identical to one another.

In addition, the drying unit 18 includes a processing area 181 in which the drying process is performed, and a delivery area 182 in which the wafer W is delivered between the transfer block 4 and the processing area 181. The processing area 181 and the delivery area 182 are arranged along the transfer area 15.

Specifically, of the processing area 181 and the delivery area 182, the delivery area 182 is disposed closer to the liquid processing unit 17 than the processing area 181. That is to say, in each of the processing books 5, the liquid processing unit 17, the delivery area 182, the processing area 181 and the supply unit 19 are arranged in this order along the transfer area 15.

(Control Device)

The substrate processing system 1 includes a control device 6. The control device 6 is, for example, a computer, and includes a control part 61 and a storage part 62.

The control part 61 includes a microcomputer including a CPU (Central Processing Unit), a ROM (Read Only Memory), a RAM (Random Access Memory), an input/output port and the like, and various circuits. The CPU of such a microcomputer reads and executes a program stored in the ROM to control the transfer devices 13 and 16, the liquid processing unit 17, the drying unit 18, the supply unit 19 and the like.

Such a program may be recorded in a non-transitory computer-readable recording medium and may be installed on the storage part 62 of the control device 6 from the recording medium. Examples of the computer-readable recording medium may include a hard disk (HD), a flexible disk (FD), a compact disk (CD), a magneto-optical disk (MO), a memory card and the like.

The storage part 62 is realized by, for example, a semiconductor memory device such as a RAM, a flash memory or the like, or a storage device such as a hard disk, an optical disk or the like.

(Liquid Processing Unit)

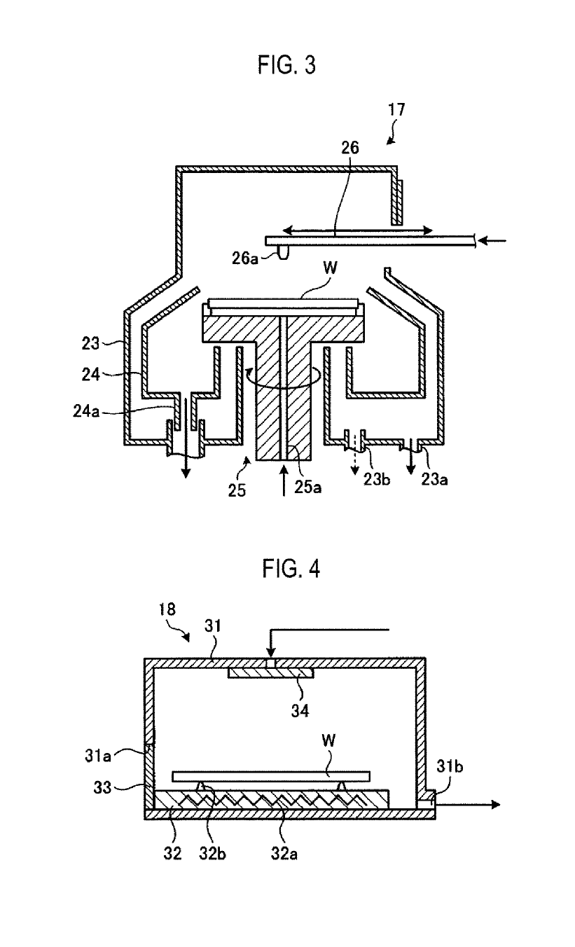

Next, a configuration of the liquid processing unit 17 will be described with reference to FIG. 3. FIG. 3 is a view showing a configuration example of the liquid processing unit 17. The liquid processing unit 17 is, for example, configured as a single-wafer type cleaning apparatus for cleaning the wafers W one by one by a spin-cleaning.

The liquid processing unit 17 holds the wafer W in a substantially horizontal posture by a wafer holding mechanism 25 disposed in an outer chamber 23 that defines a processing space, and rotates the wafer holding mechanism 25 around a vertical axis to rotate the wafer W. In addition, the liquid processing unit 17 advances a nozzle arm 26 above the rotating wafer W and performs the cleaning process on the upper surface of the wafer W by supplying a chemical liquid and a rinse liquid from a chemical liquid nozzle 26a installed at the tip of the nozzle arm 26 in a predetermined order. The nozzle arm 26 may be installed in a plural number.

In the liquid processing unit 17, a chemical liquid supply path 25a is formed inside the wafer holding mechanism 25. Further, a lower surface of the wafer W is cleaned by the chemical liquid and the rinse liquid supplied from the chemical liquid supply path 25a.

For example, the cleaning process includes removing particles and organic contaminants with a SC1 solution (mixture solution of ammonia and hydrogen peroxide) which is an alkaline chemical solution, and subsequently rinse-cleaning the wafer W with deionized water (hereinafter referred to as “DIW”) which is a rinse solution. Thereafter, the cleaning process includes removing a natural oxide film with a diluted hydrofluoric acid solution (hereinafter referred to as “DHF”) which is an acidic chemical solution, and subsequently, rinse-cleaning the wafer W with DIW.

The various chemical liquids described above are received in the outer chamber 23 or an inner cup 24 disposed inside the outer chamber 23, and are discharged from a drainage port 23a formed in the bottom of the outer chamber 23 or a drainage port 24a formed in the bottom of the inner cup 24. Further, an internal atmosphere of the outer chamber 23 is exhausted from an exhaust port 23b formed in the bottom of the outer chamber 23.

The liquid film forming process is performed after the rinse-cleaning process in the cleaning process. Specifically, while rotating the wafer holding mechanism 25, the liquid processing unit 17 supplies IPA staying in a liquid state (hereinafter referred to as an ‘IPA liquid’) onto the upper and lower surfaces of the wafer W. Thereby, DIW remaining on both surfaces of the wafer W is replaced with IPA. Thereafter, the liquid processing unit 17 gradually stops the rotation of the wafer holding mechanism 25.

The wafer W which has been subjected to the liquid film forming process is delivered to the transfer device 16 by a delivery mechanism (not shown) installed in the wafer holding mechanism 25 in a state where the IPA liquid film is formed on the upper surface of the wafer W, and is unloaded from the liquid processing unit 17. The liquid film formed on the wafer W prevents pattern collapse from occurring when the liquid on the upper surface of the wafer W is evaporated (vaporized) during the transfer of the wafer W from the liquid processing unit 17 to the drying unit 18 or during the operation of loading of the wafer W into the drying unit 18.

(Drying Unit)

Next, a configuration of the drying unit 18 will be described with reference to FIG. 4. FIG. 4 is a view showing a configuration example of the drying unit 18.

The drying unit 18 includes a processing container 31, a mounting table 32, a lid 33 and a supply part 34.

The processing container 31 is disposed in the processing area 181 (see FIG. 1). An opening 31a through which the wafer W is transferred is formed in a lateral surface of the processing container 31 so as to face the delivery area 182 (see FIG. 1). Further, a discharge port 31b from which the processing fluid is discharged is formed in the processing container 31. For example, the discharge port 31b is formed downward of another lateral surface opposed to the lateral surface in which the opening 31a is formed in the processing container 31.

The mounting table 32 moves horizontally between the processing area 181 (inside the processing container 31) and the delivery area 182, together with the lid 33. The mounting table 32 includes a heater 32a (for example, a heating wire) for heating the wafer W, and support members 32b for supporting the wafer W from below. The support members 32b are formed so that the wafer W can be delivered by the transfer device 16.

The lid 33 closes the opening 31a formed in the processing container 31 when moving from the delivery area 182 to the processing area 181.

The supply part 34 is installed, for example, in an upper portion of the processing container 31, and supplies the processing fluid supplied from the supply unit 19 (see FIG. 1) into the processing container 31. Specifically, the supply part 34 supplies the IPA gas in the drying process to dry the wafer W, and subsequently, supplies a N₂ gas into the processing container 31.

The drying unit 18 performs the drying process in a state in which the wafer W is mounted on the mounting table 32, namely in a stationary state where the rotation of the wafer W is stopped.

After the liquid film of the IPA liquid is formed on the wafer W, for example, in a case where the wafer W is dried in an air atmosphere, the pattern collapse may occur.

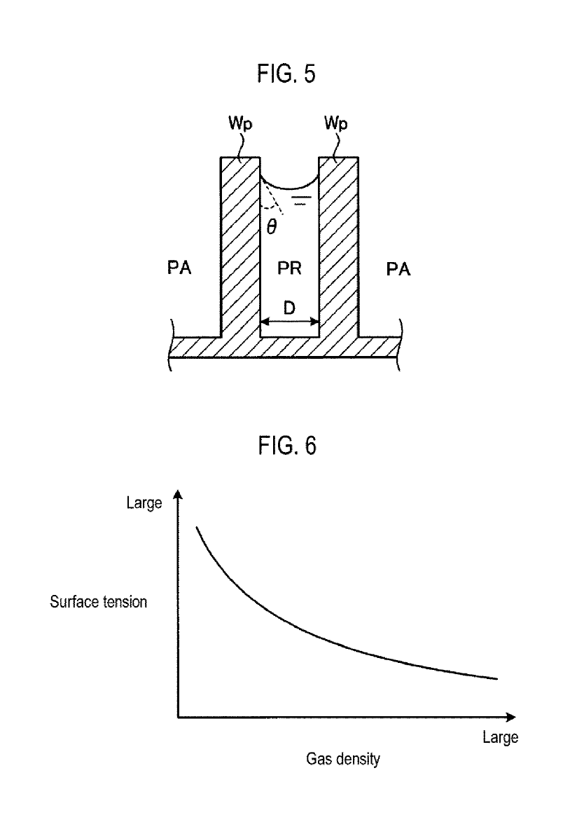

The pattern collapse will be described with reference to FIG. 5. FIG. 5 is a partially-enlarged schematic view of patterns Wp formed on the wafer W.

An IPA liquid is present between the patterns Wp formed on the wafer W. By performing the drying process, the IPA liquid existing between the patterns Wp is vaporized and the wafer W is dried. At this time, when the dried state of the IPA liquid existing at both sides of the pattern Wp is different from each other, the pattern collapse occurs due to a Laplace pressure caused by a liquid level difference of the IPA liquid. A force (pressure difference) that causes the pattern collapse can be expressed by the following equation (1).

PA−PR=2γ cos θ/D (1)

where, PA and PR represent pressures at both sides of the pattern Wp, γ represents the surface tension, θ represents a contact angle of the liquid level, and D represents a width between the patterns Wp.

The force that causes the pattern collapse is reduced by decreasing the surface tension γ. That is to say, the pattern collapse can be suppressed by decreasing the surface tension γ. The surface tension γ can be expressed by the following equation (2).

γ=k(Tc−T)M^{-2/3}(dL^{2/3}−dG^{2/3}) (2)

where, k is a constant, Tc represents a critical temperature of the liquid, T represents a temperature of the liquid, M represents a molecular weight, dL represents a liquid density, and dG represents a gas density.

In a case where the temperature T of the liquid is constant, the surface tension γ can be reduced by decreasing a difference between the liquid density dL and the gas density dG. That is to say, as shown in FIG. 6, by increasing the gas density dG around the wafer W, it is possible to reduce the surface tension γ, thereby suppressing the pattern collapse. FIG. 6 is a view showing a relationship between the gas density dG and the surface tension γ. In FIG. 6, the liquid temperature T and the liquid density dL are constant.

Therefore, in the substrate processing system 1 according to the present embodiment, in the drying unit 18, the IPA gas is supplied to increase the gas density dG around the wafer W to be larger than that of air, and subsequently, the drying process is performed in the IPA gas atmosphere. This makes it possible to reduce the surface tension γ during the drying process, thereby suppressing the pattern collapse.

[2. Substrate Processing]

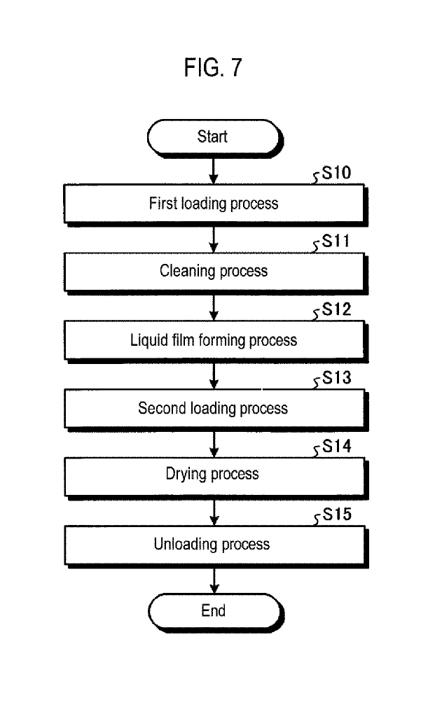

Next, a procedure of a substrate processing according to the present embodiment will be described with reference to FIG. 7. FIG. 7 is a flow chart showing the procedure of the substrate processing.

The substrate processing system 1 performs a first loading process (S10). Specifically, the substrate processing system 1 takes out a wafer W from the carrier C by the transfer device 13 and mounts the wafer W on the delivery part 14. Then, the substrate processing system 1 takes out the wafer W from the delivery part 14 by the transfer device 16, and loads the wafer W into the liquid processing unit 17.

Thereafter, the substrate processing system 1 performs a cleaning process (S11). Specifically, the substrate processing system 1 supplies various processing liquids onto the upper surface (on which a pattern is to be formed) of the wafer W by the liquid processing unit 17 to remove particles, a natural oxide film and the like from the upper surface of the wafer W.

Subsequently, the substrate processing system 1 performs a liquid film forming process (S12). Specifically, the substrate processing system 1 supplies an IPA liquid onto the upper surface of the wafer W which has been subjected to the cleaning process, to form an IPA liquid film on the upper surface of the wafer W.

Subsequently, the substrate processing system 1 performs a second loading process (S13). Specifically, the substrate processing system 1 takes out the wafer W with the IPA liquid film formed thereon, from the liquid processing unit 17 by the transfer device 16, and transfers the same to the drying unit 18.

In the drying unit 18, the IPA gas is already supplied into the processing container 31. That is, the wafer W with the IPA liquid film formed thereon is transferred into the processing container 31 into which the IPA gas has been supplied. This makes it possible to suppress the IPA liquid from being vaporized before the drying process, as compared with a case where the processing container 31 is filled with air, thereby suppressing the pattern collapse.

Subsequently, the substrate processing system 1 performs a drying process (S14). Specifically, the substrate processing system 1 supplies the IPA gas from the supply part 34 so that the gas density dG around the wafer W is larger than that of air, and dries the wafer W by heating the wafer W with the heater 32a. For example, after a preset predetermined period of time, the substrate processing system 1 supplies a N₂ gas from the supply part 34 to replace the surrounding atmosphere of the wafer W from the IPA gas with the N₂ gas. The predetermined period of time is a period of time during which the drying of the wafer W is completed. In addition, the drying process is performed while discharging the processing fluids (the IPA gas and the N₂ gas) from the discharge port 31b.

Thereafter, the substrate processing system 1 performs an unloading process (S15).

Specifically, the substrate processing system 1 takes out the wafer W which has been subjected to the drying process, from the drying unit 18 by the transfer device 16, and mounts the same on the delivery part 14. Then, the substrate processing system 1 transfers the wafer W from the delivery part 14 to the carrier C by the transfer device 13.

In this manner, the substrate processing system 1 performs the substrate processing on each wafer W.

[3. Effects]

The substrate processing system 1 forms an IPA liquid film on the front surface of the wafer W, followed by heating and drying the wafer W in a state where the gas density dG around the wafer W with the IPA liquid film formed thereon is larger than that of air. Specifically, the substrate processing system 1 dries the wafer W in the IPA gas atmosphere around the wafer W. This makes it possible to reduce the surface tension γ of the IPA liquid existing between the patterns Wp of the wafer W during the drying process of drying the wafer W. Therefore, it is possible to suppress the pattern collapse from occurring during at the time of drying process.

The substrate processing system 1 replaces the IPA gas with the N₂ gas after the drying of the wafer W in the drying process is completed. This makes it possible to prevent the IPA gas from leaking out from the drying unit 18 when taking out the dried wafer W from the drying unit 18.

The substrate processing system 1 performs the drying process in a state where the wafer W is kept stationary. This makes it possible to suppress unevenness in the dry state of the wafer W, thereby suppressing the pattern collapse, as compared with a case where the drying process is performed while the wafer W is being rotated.

[4. Modifications]

A substrate processing system according to a modification may perform the liquid film forming process and the drying process inside a single unit, namely inside a single chamber. For example, the substrate processing system according to the modification may perform the drying process in the liquid processing unit 17. This makes it possible to reduce the size of the substrate processing system and omit the process of transferring the wafer W with the IPA liquid film formed thereon, thus performing the substrate processing in a short period of time.

In addition, the substrate processing system according to the modification may heat the wafer W by supplying, for example, a heated IPA gas in the drying unit 18. Further, the substrate processing system according to the modification may perform the heating of the IPA gas in the supply unit 19. Further, the substrate processing system according to the modification may heat the wafer W in the drying unit 18 by circulating hot water inside the processing container 31.

Further, the substrate processing system according to the modification may vaporize IPA staying in a liquid state by a vaporizer (not shown) in the supply unit 19 to generate an IPA gas and supply the generated IPA gas from the supply part 34 into the processing container 31. This makes it possible to easily control a concentration of the IPA gas.

Further, the substrate processing system 1 according to the above embodiment performs the drying process in a state where the wafer W is kept stationary, but the present disclosure is not limited thereto. A substrate processing system according to another modification may perform the drying process while rotating the wafer W.

According to the present disclosure in some embodiments, it is possible to suppress pattern collapse.

Additional effects and modifications can be easily derived by those skilled in the art. Thus, the broader aspects of the present disclosure are not limited to the specific details and representative embodiments shown and described above. Accordingly, various modifications are possible without departing from the spirit or scope of the general inventive concept as defined by the appended claims and their equivalents.

What is claimed is:

1. A method of processing a substrate, comprising:
forming a liquid film of an organic solvent on a front surface of the substrate; and
drying the substrate with the liquid film formed thereon by heating the substrate in a state where a gas density around the substrate is larger than a gas density of air.

2. The method of claim 1, wherein the drying the substrate with the liquid film formed thereon includes drying the substrate in an organic solvent gas atmosphere.

3. The method of claim 2, wherein the drying the substrate with the liquid film formed thereon includes replacing the organic solvent gas atmosphere with an inert gas atmosphere after drying the substrate.

4. The method of claim 1, wherein the drying the substrate with the liquid film formed thereon includes drying the substrate in a state where the substrate is kept stationary.

5. The method of claim 1, wherein the forming a liquid film and the drying the substrate are performed in a single chamber.

6. A substrate processing apparatus comprising:
a forming part configured to form a liquid film of an organic solvent on a front surface of a substrate; and
a drying part configured to dry the substrate with the liquid film formed thereon by heating the substrate in a state where a gas density around the substrate is larger than a gas density of air.
